(19) United States
(12) Patent Application Publication
(10) Pub. No.: US 2015/0187675 A1
(43) Pub. Date: Jul. 2, 2015

(54) METHODS AND APPARATUS FOR DISSIPATING HEAT FROM A DIE ASSEMBLY

(71) Applicants: Jinbang TANG, Chandler, AZ (US); Weng Foong YAP, Chandler, AZ (US)

(72) Inventors: Jinbang TANG, Chandler, AZ (US); Weng Foong YAP, Chandler, AZ (US)

(21) Appl. No.: 14/144,911

(22) Filed: Dec. 31, 2013

(51) Int. Cl. H01L 23/367; H01L 21/48; H01L 23/31; H01L 21/56

(52) U.S. Cl. CPC H01L 23/367; H01L 21/56; H01L 21/4871; H01L 23/3114

(57) ABSTRACT

An embodiment of a method facilitates heat dissipation from a die assembly. The method includes removing material from a first side of a die of the die assembly to create a set of recesses in the first side of the die, and depositing a metal-containing layer over the first side of the die to form a heat spreader that contains a set of contours that fill the set of recesses. An embodiment of a die assembly fabricated using the method includes an assembly substrate and a die with a set of recesses formed in a first side of the die. The die assembly also includes an encapsulant formed on the assembly substrate that is absent at least over the set of recesses, and a heat spreader affixed to the first side of the die that includes a set of contours that fill the set of recesses in the die.

### FIELD

The present disclosure relates generally to die assemblies and more particularly to dissipating heat generated by dies within die assemblies.

### BACKGROUND

To remain competitive in the marketplace and to meet consumer demand for “smarter” electronics, manufacturers are building and marketing devices of increasing complexity. This observation led to Moore's law, which states that the number of transistors included in integrated circuits (ICs) doubles approximately every two years. Device manufacturers rely on vendors to supply ICs that are fabricated as modular packages or die assemblies. Multiple die assemblies from numerous vendors can be connected to a single printed circuit board (PCB) to create a next-generation apparatus that can outperform older devices.

Packing more processing power into smaller devices necessitates creating die packages with smaller form factors. This, in turn, places a larger number of transistors, and other electronic components, in close proximity to one another, which generates heat. To keep current and future die packages functioning reliably while they generate more heat per unit volume, advanced techniques for cooling die packages are needed.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a cross-sectional side view of a die assembly, in accordance with an embodiment of the present teachings.

FIG. 2 is a flow diagram of a method for enabling heat dissipation from a die assembly, in accordance with an embodiment of the present teachings.

FIG. 3 is a pair of cross-sectional side views and top views of thermal via distributions, in accordance with embodiments of the present teachings.

FIG. 4 is a pair of top views of pitting patterns in an exposed surface of a die, in accordance with embodiments of the present teachings.

FIG. 5 is a cross-sectional side view and a top view of a die assembly, in accordance with an embodiment of the present teachings.

FIG. 6 is a cross-sectional side view and a top view of a die assembly, in accordance with an embodiment of the present teachings.

FIG. 7 is a cross-sectional side view of a die assembly, in accordance with an embodiment of the present teachings.

FIG. 8 is an oblique view and cross-sectional side view of an intermediate layer between a die and a heat spreader, in accordance with an embodiment of the present teachings.

The present disclosure is illustrated by way of example and is not limited by the accompanying figures, in which like references indicate similar elements. Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure. In addition, the description and drawings do not necessarily require the order presented. It will be further appreciated that certain actions and/or steps may be described or depicted in a particular order of occurrence while those skilled in the art will understand that such specificity with respect to sequence is not actually required.

The apparatus and method components have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein.

### DETAILED DESCRIPTION

In accordance with an embodiment of the present disclosure is a method for enabling heat dissipation from a die assembly. The method includes removing material from a first side of a die of the die assembly to create a set of recesses in the first side of the die. The method further includes depositing a metal-containing layer over the first side of the die to form a heat spreader that contains a set of contours that fill the set of recesses in the first side of the die.

In accordance with another embodiment of the present disclosure is a die assembly that includes an assembly substrate and a die having a first side and a second opposing side, wherein the die is mounted to the assembly substrate at the second side and a set of recesses is formed in the first side of the die. The die assembly also includes an encapsulant formed on the assembly substrate, wherein the encapsulant at least partially embeds the die within the die assembly, and the encapsulant is absent at least over the set of recesses formed in the first side of the die. The die assembly further includes a heat spreader affixed to the first side of the die and configured to conduct heat away from the die, wherein the heat spreader includes a set of contours that fill the set of recesses formed in the first side of the die.

Also in accordance with an embodiment of the present disclosure is a die assembly that includes an assembly substrate and a die having a first side and a second opposing side, wherein the die is mounted to the assembly substrate at the second side and a set of recesses is formed in the first side of the die, wherein the die further includes a plurality of thermal vias configured to transfer heat generated within the die to the first side of the die, wherein the plurality of thermal vias are exposed at the first side of the die. The die assembly further includes an encapsulant formed on the assembly substrate, wherein the encapsulant at least partially embeds the die within the die assembly, and the encapsulant is absent at least over the set of recesses and over one or more areas where the plurality of thermal vias are exposed at the first side of the die. A heat spreader is included in the die assembly that is affixed to the first side of the die and configured to conduct heat away from the die, wherein the heat spreader includes a set of contours that fill the set of recesses formed in the first side of the die. The die assembly also includes a first thin film disposed between the first side of the die and the heat spreader, wherein the first thin film is configured to limit diffusion of metal into the die, and a second thin film disposed between the first thin film and the heat spreader, wherein the second thin film is configured to affix the heat spreader to the first side of the die.

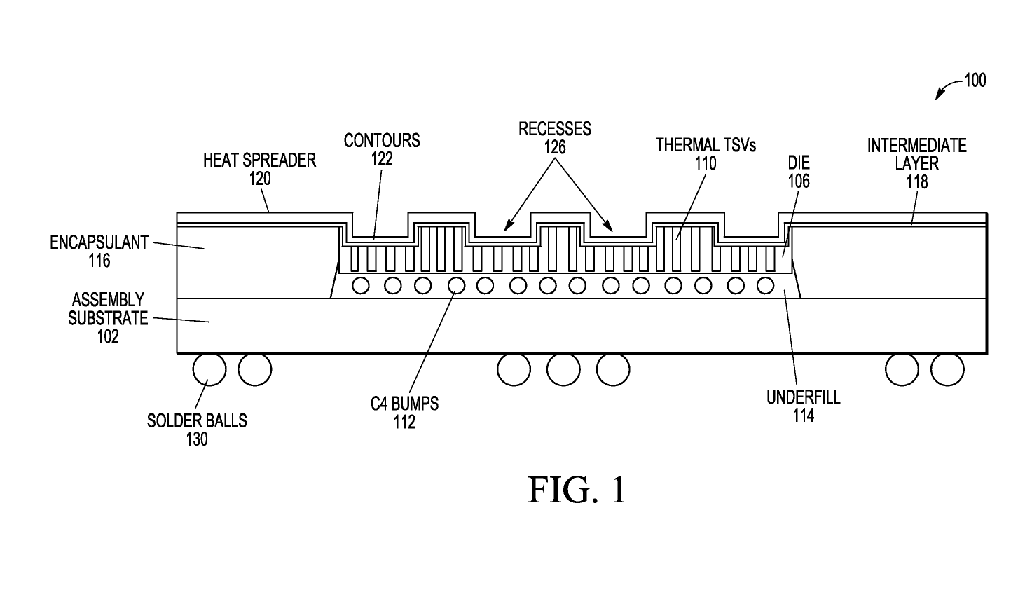

Referring now to the drawings, and in particular FIG. 1, a cross-sectional view of a die assembly consistent with some embodiments of the present teachings is shown and indicated at 100. As used herein, a die assembly, also referred to as a die package and an integrated circuit package, is defined as one or more dies coupled to and/or included within a single integrated physical unit or package. In an embodiment, a die assembly provides both protection against physical damage to the one or more dies within the assembly and electrical contacts for establishing signal connections between the one or more dies and another electronic device, such as a PCB, with which the die assembly is interfaced. A die, also referred to as an integrated circuit, as used herein, is defined as a piece of base material, such as a piece of semiconductor material, upon which one or more electronic components and/or circuits are fabricated or formed.

In a particular embodiment, a semiconductor fabrication process is used to fabricate the one or more dies contained in the die assemblies illustrated in the figures. Accordingly, die assemblies illustrated in the figures are referred to hereafter as semiconductor die assemblies, and thermal vias are referred to hereafter as thermal through-substrate vias (TSVs). However, the present teachings are not limited by the particular fabrication process used to fabricate a die contained in a die assembly.

The semiconductor die assembly 100 is shown to include: solder balls 130, an assembly substrate 102, C4 bumps 112, an underfill material 114, a die 106 having therein a set of thermal TSVs 110 and a set of recesses 126 in a first side (shown as the upper side) of the die 106, an encapsulant 116, an intermediate layer 118, and a heat spreader 120. While the particular die package shown at 100 is a flip-chip ball grid array (BGA) package, the teachings of the present disclosure are applicable to other types of die packages that include, but are not limited to: pin grid array (PGA) packages; land grid array (LGA) packages; fan-out wafer level packaging (FOWLP) packages, also referred to as redistributed chip packaging (RCP) packages; and system in package (SiP) packages. Further, each type of die package can possess characteristics that allow it to be identified as being of a particular subtype. BGA packages to which the present teachings can be applied, for example, include but are not limited to: plastic BGA packages, ceramic BGA packages, fine-pitch BGA packages, and wafer level BGA packages.

The assembly substrate 102, also referred to herein simply as a substrate, provides a foundation that structurally supports the die package 100. For some embodiments, a stiff assembly substrate 102 is formed from materials, such as plastics and ceramics, that add planarity and rigidity to the die package 100. The assembly substrate 102 for such an embodiment may include and support a leadframe (not shown) that provides signal connections between a topside of the substrate 102, to which the die 106 is mounted, and an underside of the substrate 102 where the solder balls 130 are located.

The solder balls 130 provide the means to electrically interconnect the BGA die package 100 to a PCB. Electrically conductive materials, such as alloys of tin and lead, are used to form the solder balls 130, which are aligned with electrical contacts on the PCB. With the application of heat, the solder balls 130 are reflowed to provide individually soldered signal connections between each solder ball 130 and its respective contact on the PCB.

The C4 bumps 112 electrically connect the die 106 in a flip-chip configuration to the substrate 102. The underfill 114 is added to protect the C4 bumps 112 from moisture and other environmental hazards while also providing structural support for the connection between the die 106 and the substrate 102. An underfill material is used that bonds well with the die 106, including any passivation applied to the die 106, and also with the assembly substrate 102.

The encapsulant 116 formed on the assembly substrate 102 at least partially embeds the die 106 within the semiconductor die assembly 100. As used herein, an encapsulant is defined as a material used to hold, contain, support, mount, enclose, encapsulate, or seal a die within a semiconductor die assembly to form a single unit. Encapsulants, such as epoxy or other molding compounds, protect the die 106 within the die package from moisture and other environmental hazards. The encapsulant 116 can be applied using a variety of techniques, one of which includes forming the encapsulant 116 by injecting it into a mold. In a particular embodiment, the encapsulant 116 is injected into a mold that holds multiple die packages, which are then separated into individual die packages (e.g., by cutting) after the encapsulant 116 cures.

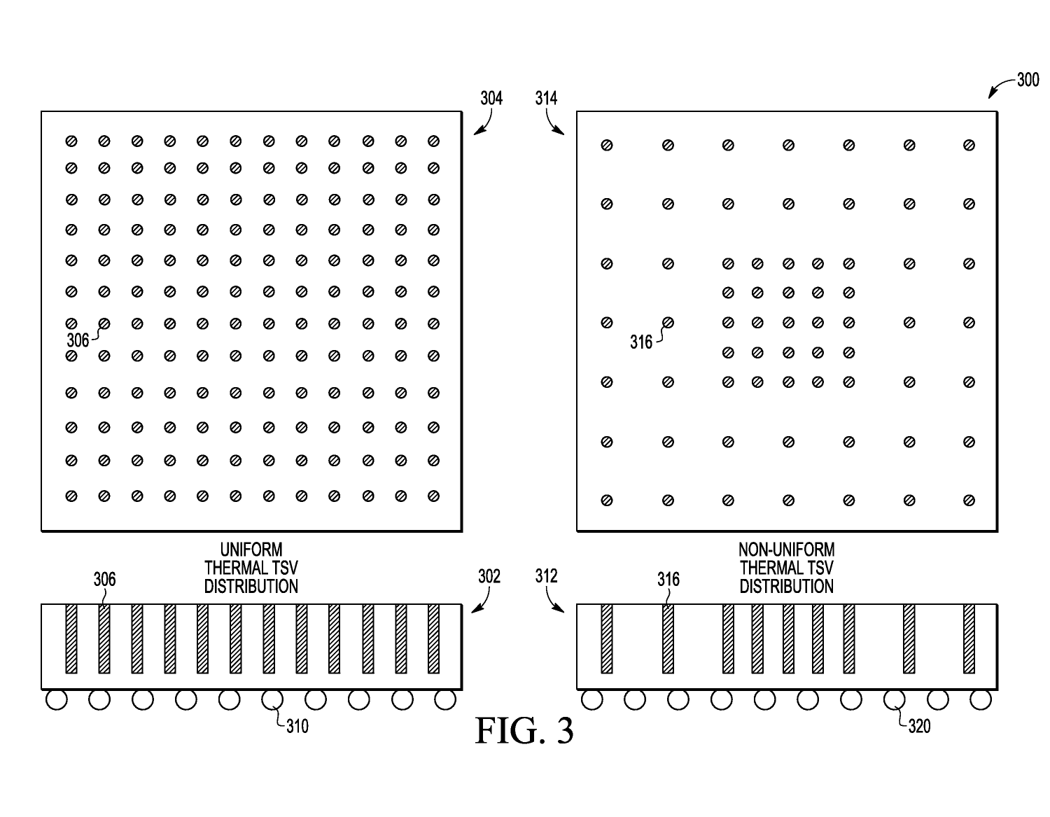

The plurality of thermal TSVs 110 formed and distributed within the die 106 are configured to transfer heat generated at an active side of the die 106 to the opposing side of the die 106. The active side of a die, as defined herein, is the side of the die on which the electronic components that perform the function of the die are located. By contrast, the opposite side of the die, the side which does not include active electronic components, is the non-active side of the die. For example, for each die shown in FIGS. 1, 3, 5, 6, and 8, the active side of the die is the lower side as illustrated, and the inactive side is the upper side, where the heat spreader is attached. While a thermal TSV and a signal TSV can be constructed from similar material (e.g., copper), a signal TSV establishes electrical signal connections between electrical contacts. Conversely, a thermal TSV is not a conduit for an electrical signal. Instead, the thermal TSVs 110 act as “heat pipes” and are, thus, conduits for transferring heat. Turning momentarily to FIG. 3, thermal TSVs are described in greater detail.

In FIG. 3, two views for each of two dies having different distributions of thermal TSVs are shown and indicated at 300. A cross-sectional view and a top view of a first die with a uniform distribution of thermal TSVs are shown on the left-hand side of FIG. 3 at 302 and 304, respectively. On the right-hand side of FIG. 3, similar cross-sectional and top views are shown for a second die with a non-uniform distribution of thermal TSVs at 312 and 314, respectively. For the top view 304 of the first die, a set of 144 thermal TSVs 306 are shown arranged symmetrically within the die in a square pattern with a regular spacing between TSVs. As defined herein, the number of elements within a set is open-ended but can be as few as one. In the cross-sectional view 302 of the first die, C4 bumps 310 on the lower side of the die indicate the die is mounted in a flip-chip configuration with its active side down. Similarly, C4 bumps 320 are also shown on the lower side of the second die.

The cross-sectional view 302 shows an embodiment where the thermal TSVs 306 begin at the upper surface on the non-active side of the first die and extend down into the die without penetrating all the way through to the lower surface on the active side of the die. Instead, the thermal TSVs 306 stop short of the active electronic components located on the active side of the die. In one embodiment, the thermal TSVs 306 extend into the first die to a depth within a range of about 82% to about 98% of the thickness of the die, although the thermal TSVs 306 may extend to shallower or deeper depths, as well. In another embodiment, the thermal TSVs 306 extend into the first die to within about 10 micrometers (μm) of the lower surface of the die, although the thermal TSVs 306 may extend to shallower or deeper depths, as well. The thermal TSVs 306 heat up above the active electronic components and conduct the thermal energy to the upper surface on the non-active side the die, where the heat is transferred to a heat spreader. In an alternate embodiment, electronic components on the active side of a die are arranged during fabrication to form spaces that allow thermal TSVs to penetrate through to the lower surface of the die, thereby improving the removal of heat from the active side of the die during operation.

For other embodiments, at least a portion of a plurality of thermal TSVs within a die has a higher spatial density within a portion of the die that will operate at an elevated temperature relative to an average operational temperature of the die. Such an embodiment is depicted by the top view of the second die 314 in which 65 thermal TSVs 316 are arranged spatially to form a non-uniform pattern. At the center of the die, 25 thermal TSVs are spaced closer together than the remaining 40 thermal TSVs that are distributed at the outer edges of the die. For such an embodiment, during operation, a higher concentration of active components at or near the center of the die results in a “hot spot” or an elevated temperature at or near the center of the die relative to non-central areas of the die. By placing a higher concentration of thermal TSVs in areas that would otherwise run hotter than the average temperature of the die during operation, the temperature of those areas may be reduced. The cross-sectional view 312 of the second die shows the spacing between the thermal TSV shown at 316 and its nearest neighboring TSVs within the die is greater than the spacing appearing at or near the center of the die, where the operating temperature is or would otherwise be elevated.

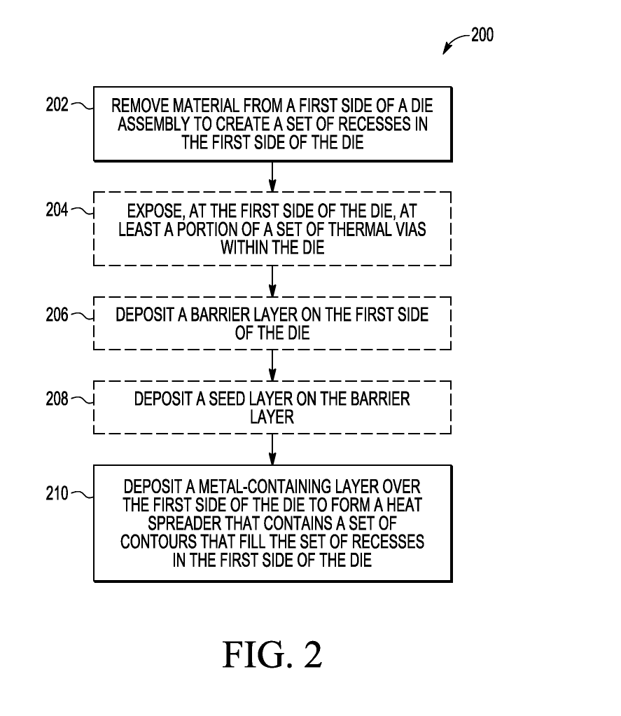

FIG. 2 shows a logical flow diagram 200 of a method for enabling heat dissipation from a die assembly, consistent with the teachings herein. In particular, the method 200 includes removing 202 material from a first side of a die of a die assembly to create a set of recesses in the first side of the die. The method 200 also includes depositing 210 a metal-containing layer over the first side of the die to form a heat spreader that contains a set of contours that fill the set of recesses in the first side of the die. For one embodiment, the method 200 optionally includes exposing 204, at the first side of the die, at least a portion of a set of thermal vias within the die, wherein the metal-containing layer is also deposited 210 over the exposed portion of the set of thermal vias. For another embodiment, the method 200 optionally includes depositing 206 a barrier layer on the first side of the die and depositing 208 a seed layer on the barrier layer, wherein the metal-containing layer is deposited 210 over the die by depositing it on the seed layer. In the following paragraphs, the method 200 is described in greater detail with reference to the die package 100.

For the die package 100, a set of four recesses 126 is created 202 in the backside of the die 106, which is mounted in a flip-chip configuration with its active side down. As used herein, a backside of a die is defined to be the non-active side of the die, and the topside of a die is defined to be the active side of the die. Additionally, in an embodiment, a first side of a die is the side of the die in which a set of one or more recesses is created, and a second side of a die is the side of the die that is mounted to an assembly substrate. Thus, how a die is mounted and recessed determines the first and second side of the die, irrespective of the active and non-active sides of the die. A recess is defined herein to be a cavity, void, incurvation, depression, gap, hole, pit, channel, or hollow that penetrates beyond a first surface of die of a die into the interior of the die at the first side of the die. The first surface of the die, as used herein, refers to the two-dimensional plane overlaying the first side of the die where the set of recesses is created. The set of recesses created in the backside of the die 106 increases the surface area of the backside of the die 106 allowing for more effective cooling of the die 106. For some embodiments, the set of recesses 126 extend into the die 106 to a depth of between about 10 μm and about 300 μm, stopping short of the active electronic components within the die 106. In other embodiments, the recesses 126 may extend to greater or smaller depths, including extending into the die 106 beyond the depth of the lower extent of the active electronic components if there is sufficient distance between electronic components to allow for the removal of material from the die 106 without damaging the electronic components.

For several embodiments, a set of recesses is created in a first side of a die by removing 202 material from the first side of the die. A first method to remove 202 material does so by a physical means. For example, grinding, cutting, or drilling into the first side of the die results in the creation of recesses in the die. Another method involves using chemicals to etch or dissolve portions of the first side of the die to create recesses. A third method uses directed energy to create recesses. For example, a laser cuts or burns one or more recesses into the first side of the die. In a particular example, the laser is able to cut a recess between active electronic components within the die 106, to a depth that exceeds the depth of the lower extent of the electronic components within the die. Such a laser cutting process may be employed, for example, where there is about 20 or more μm distance between the electronic components, although the process may be employed when there is less separation distance, in other embodiments.

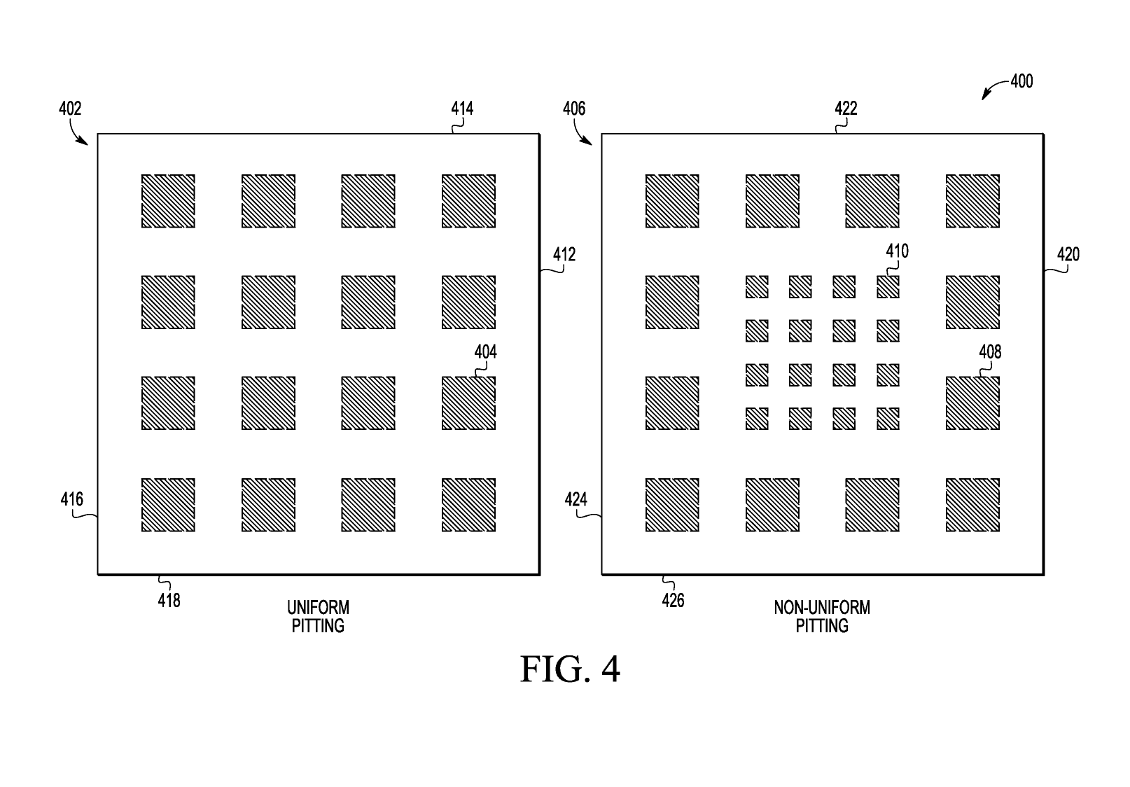

In a particular embodiment, the set of recesses in the first side of the die form a set of pits in the first side of the die. As used herein, a pit is defined as a recess having a perimeter, the perimeter being level with the first surface of a die, that is either contained within the edges of the die or intersects at most one edge of the die. Turning momentarily to FIG. 4, two schematic diagrams illustrating a top view of pits recessed within a first side of a die are shown and indicated at 400. Specifically, a first die shown at 402 includes a uniform array of substantially identical pits 404 having a constant spacing. Each pit 404 is defined by a square perimeter that is contained within four edges 412, 414, 416, 418 of the die. For an embodiment, the die 402 represents the die 106 in cross section with the pits 404 representing the recesses 126.

While the pits shown at 404 are square, different embodiments may include pits of any shape and size. Further, the shape of a pit may change as a function of its depth within a die. For example, a pit may have a square perimeter level with a first surface of a die with the shape changing within the die to a conical one that comes to a point at its level of deepest penetration. The shape of a pit may also be independent of its depth, creating a three-dimensional cavity within a die that resembles a cube or cylinder, for example.

A second die shown at 406 includes a non-uniform distribution of pits having different sizes and spacings. Larger square pits 408 are shown along outer edges 420, 422, 424, 426 of the die while the center portion of the die's first side includes an array of more closely packed pits 410 having a relatively smaller size. For an embodiment, creating a higher concentration of more densely packed pits 410 over a portion of the die 406, e.g., the center portion, that has a higher operating temperature relative to the average operating temperature of the die 406 allows for more efficient cooling due to the increased surface area of the many smaller pits. In a further embodiment, the higher concentration of more densely packed pits 410 is created above a portion of the die 406 that also contains a higher density of thermal TSVs. Such an embodiment results from superimposing the distribution of pits shown at 406 over the distribution of thermal TSVs shown at 314, for example.

Turning back to FIG. 2, the heat spreader 120 is formed by depositing 210 a metal-containing layer over the first side of the die 106 in which the recesses 126 are created. A layer, as defined herein, is an expanse or stratum of material that covers, in whole or in part, a die. For a set of multiple layers, one layer is in direct contact with the die while other layers are in direct contact with their neighboring layers. A metal-containing layer is a layer of material that includes at least one type of metallic element. For a particular embodiment, the metal-containing layer that forms the heat spreader 120 is made from copper. In other embodiments, a different metal, or an alloy or multiple metals, is used. Metals used for the heat spreader 120 are selected based on having advantageous characteristics. In comparing metals, a favorable metal has a relatively high thermal conductivity and a relatively low cost. Copper, for example, has a higher thermal conductivity than gold (401 versus 310 watts per meter per kelvin (W/mK)) and is also more cost effective. Other advantageous characteristics for metals used in a heat spreader 120 include good adhesion to neighboring layers and low reactivity with those layers (e.g., limiting galvanic corrosion) or the surrounding environment (e.g., limiting atmospheric oxidation).

The metal-containing layer is deposited 210 to form the heat spreader 120, which includes a set of contours 122 that penetrate into the first side of the die 106 by filling the set of recesses 126 created in the first side of the die 106. A contour, as defined herein, is a protrusion or deviation in the surface of a heat spreader placed against a die. At a minimum, a contour of the heat spreader extends into the die at a recess beyond the first surface of the die. A contour fills a recess when the contour follows or conforms to the recess. The entire recess need not be occupied by the contour for the recess to be filled. It is enough that any amount of a metal-containing material that forms the contour of a heat spreader is located within the recess.

The heat spreader 120 acts as a heat exchanger that transfers thermal energy from the die 106 to the surrounding environment. Creating 202 the set of recesses 126 within the first side of the die 106 and allowing the contours 122 of the heat spreader 120 to penetrate down into the die 106 and fill those recesses 126 increases the surface area of the heat spreader that is in thermal contact with the die 106. Due to the increase in surface area in thermal contact with the die 106, the heat spreader can draw a larger amount of heat per unit time out of the die 106 while it is operating. Moreover, the thermal TSVs 110 add to the rate at which heat generated within the die 106 is transferred to the heat spreader 120.

In this embodiment, at least a portion of the thermal TSVs 110 formed within the die 106 are exposed 204 at the first surface of the die 106 when material is removed 202 from the first side of the die 106 to form the set of recesses 126. For a particular embodiment, the thermal TSVs 110 are exposed 204 over the entire first surface of the die 106. The TSVs 110 are exposed 204 when they are not covered by the encapsulant 116 and can thus come in direct contact with the heat spreader 120 or the intermediate layer 118. In another embodiment, thermal TSVs 110 are exposed 204 by forming the encapsulant 116 such that the encapsulant 116 is absent above the first surface of the die 106. This is accomplished, for example, by forming the encapsulant 116 using a mold. Depositing 210 the metal-containing layer over the exposed portion of the thermal TSVs 110 then forms a good thermal contact between the TSVs 110 and the heat spreader 120.

As heat from the die 106 enters the heat spreader 120, facilitated by the thermal TSVs 110 and the increased surface area of the recesses 126 within the die 106, the heat is conducted away from the die 106. In the embodiment shown at 100, the heat spreader 120 extends over the encapsulant 116 beyond the boundaries of the die 106. This feature both carries heat away from the die 106 and also allows for more surface area to radiate the heat to the environment. The heat spreader is of sufficient thickness, typically greater than about 10 μm and closer to about 100 μm, to effectively move heat away from the die. In other embodiments, the heat spreader may be thicker or thinner than the above-given range. Moving heat entering the heat spreader 120 away from the die 106 maintains a temperature gradient between the heat spreader 120 and the die 106 that drives the flow of heat from the die 106 into the heat spreader 120.

For a particular embodiment, a first recess of the set of recesses 126 is created 202 in the first side of the die 106 and a first contour of the set contours of the heat spreader 120 fills the first recess in a location over a portion of the die having an elevated operational temperature relative to an average operational temperature over the first side of the die. This places more metal-containing thermally conductive material in contact with the die 106 where a greater amount of heat needs to be dissipated.

The intermediate layer 118 disposed between the first side of the die 106 and the heat spreader 120 can include a single layer of a material or multiple layers of different materials, also referred to herein as thin films. These layers or films are thin in that their thickness is less than the thickness of the heat spreader 120, in an embodiment. The thickness of individual layers is based, for instance, on their function. One of the functions of the heat spreader 120 is to move heat away from the die 106, which is facilitated by the heat spreader having a greater thickness. Functions performed by the intermediate layer 118 can be accomplished through the use of relatively thinner films. In a first example, a first thin film disposed between the first side of the die 106 and the heat spreader 120 is configured to limit diffusion of metal into the die 106. In a second example, a second thin film disposed between the first thin film and the heat spreader 120 is configured to affix the heat spreader to the first side of the die.

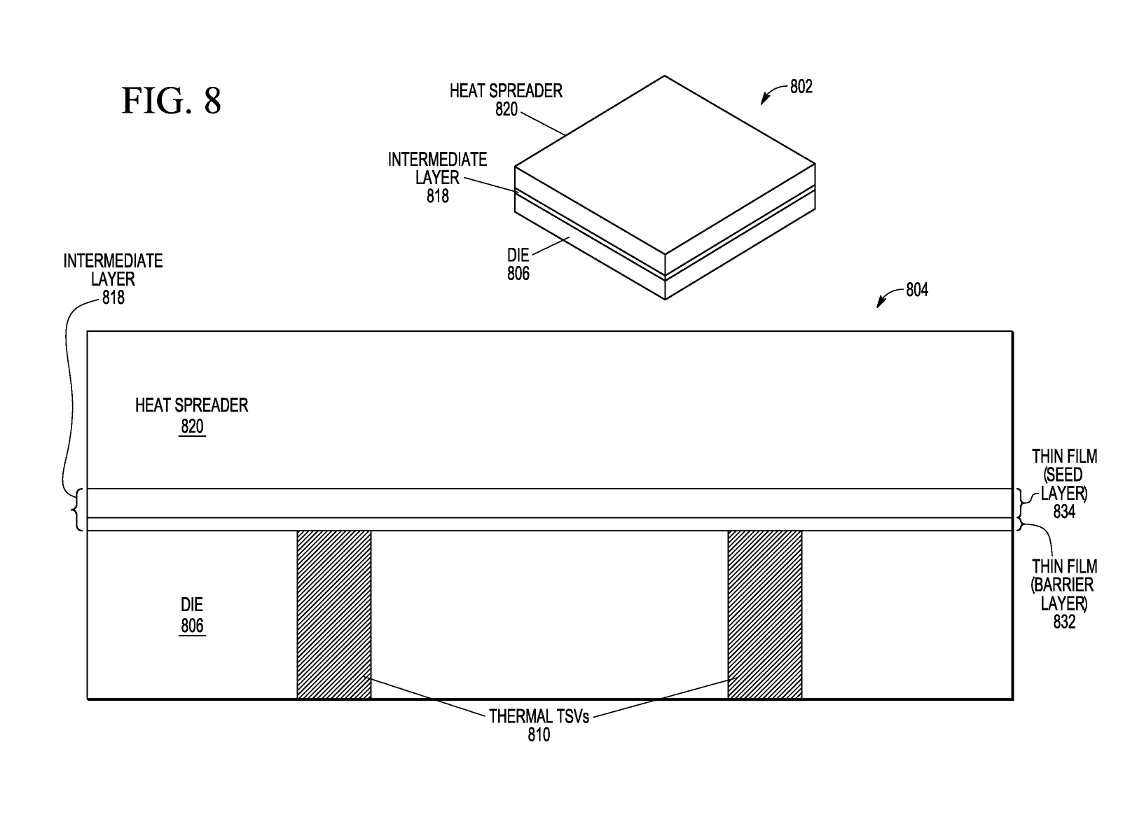

For one embodiment, the first thin film forms a barrier layer, which is deposited on the first side of the die 106, and the second thin film forms a seed layer, which is deposited on the barrier layer. The metal-containing layer that forms the heat spreader 120 is then deposited 210 over the first side of the die 106 by depositing (e.g., plating, evaporating, or otherwise depositing) it on the seed layer. In a further embodiment, the one or more layers of the intermediate layer 118 also fills the recesses 126 along with the contours 122 of the heat spreader 120. A more detailed description of the intermediate layer 118 is later described with reference to FIG. 8.

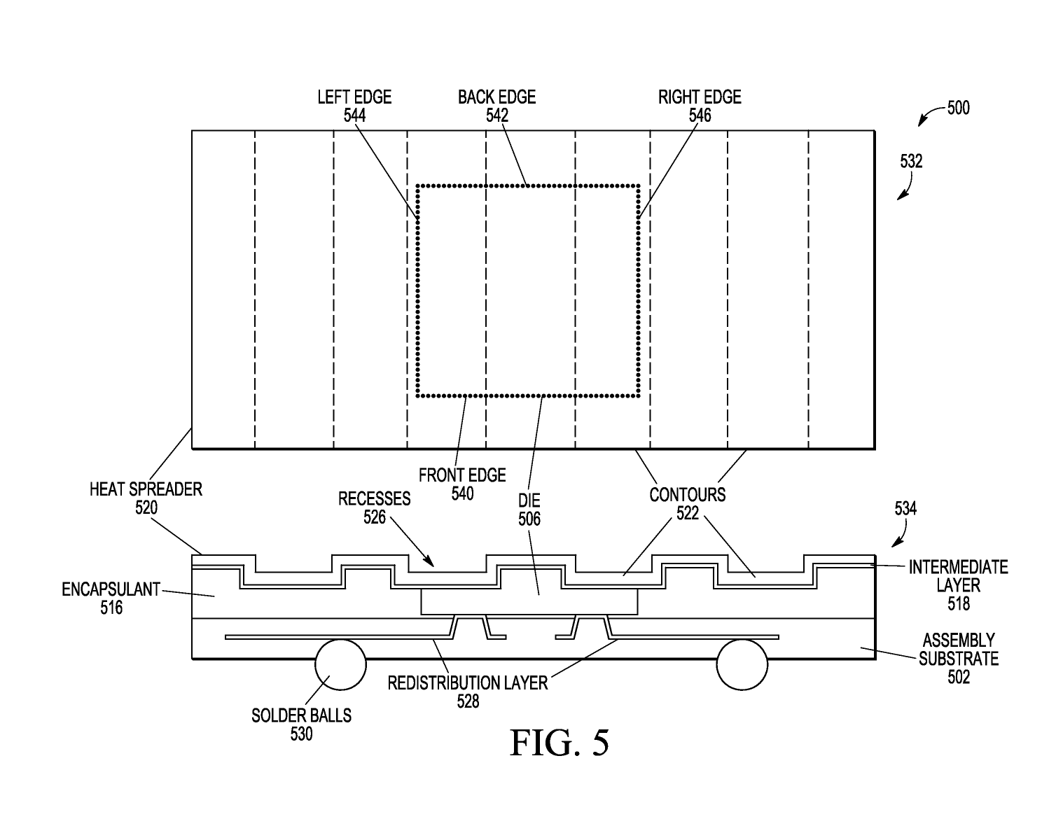

Creating a set of recesses in a first side of a die is described in additional detail with reference to FIG. 5. FIG. 5 shows a semiconductor die assembly 500, consistent with an embodiment of the present teachings, in cross section at 534 and in a top view at 532. Specifically, the semiconductor die assembly 500 is a fan-out wafer level packaging package, also referred to as an RCP package. Included within the die package 500 is: a die 506 having therein a set of recesses 526, an assembly substrate 502, solder balls 530, encapsulant 516, an intermediate layer 518, a heat spreader 520 having contours 522, and a redistribution layer 528. The redistribution layer 528 is formed, by etching or some other means, to create individual fan-out connectors that establish signal connections between the die 506 and the solder balls 530. In alternate embodiments, a semiconductor die assembly may include multiple redistribution layers configured for this purpose.

For the embodiment shown at 500, the set of recesses 526 in the first side of the die and the set of contours 522 of the heat spreader form a set of channels across the first side of the die in a single direction, for example, from a front edge 540 of the die 506 to a back edge 542 of the die 506. As used herein, a channel is defined as a recess having edges, the edges being level with the first surface of a die, that intersect at least two edges of the die. A channel, therefore, “connects” or “touches” at least two edges of a die. In the cross-sectional view 534, the two parallel channels each connect the front edge 540 of the die 506 to the back edge 542 of the die 506. Additionally, each of the two channels is shown to completely overlap either a left edge 544 or a right edge 546 of the die 506. In alternate embodiments, recesses forming channels cross edges of a die but do not completely overlap any one edge of the die.

As indicated in the cross-sectional 534 and top 532 views of the die package 500, the (innermost) contours 522 of the heat spreader 520 fill the recesses 526 within the first side of the die 506 by following or conforming to the recesses 526. For the illustrated embodiment, the heat spreader 520 includes additional (outermost) contours 522 that align with cavities in the die package 500 where portions of the encapsulant 516 are removed or displaced. This increases the surface area of the heat spreader 520 and makes it more effective at conducting heat away from the die 506 and radiating that heat to the environment. However, in a different embodiment similar to the embodiment shown by FIG. 1, the contours and recesses are contained only within the die and do not extend to other areas of the die package.

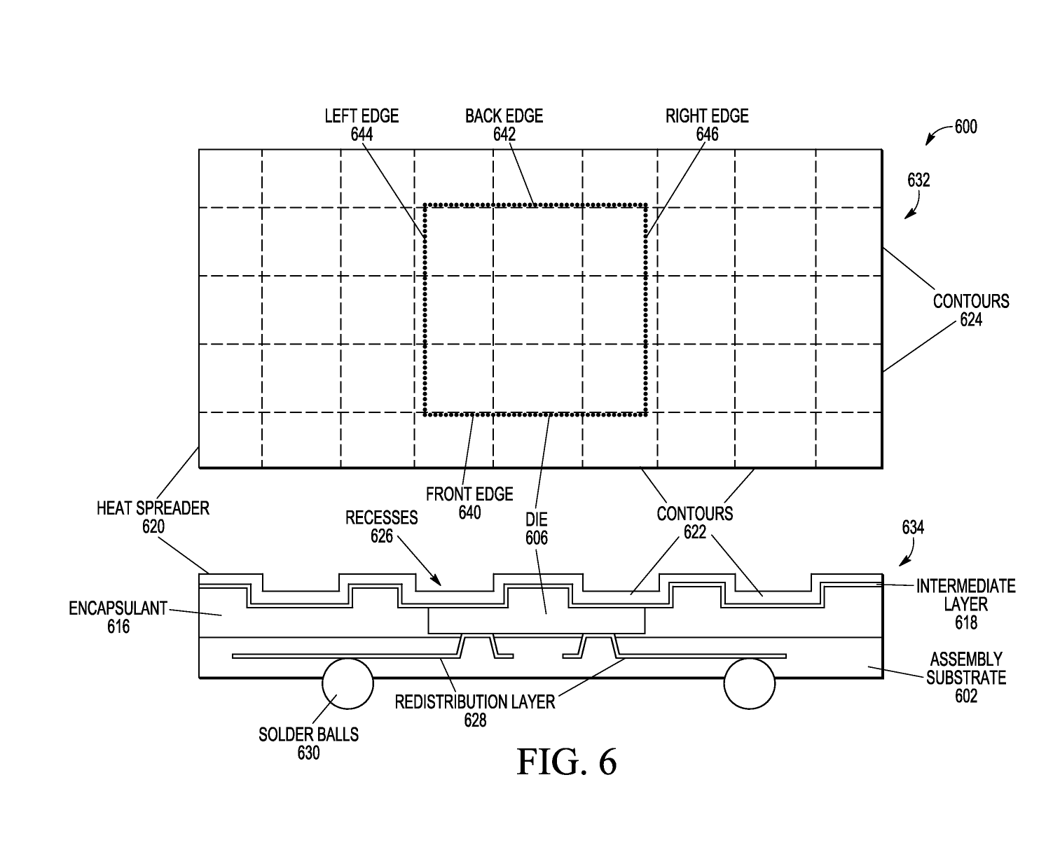

For another embodiment, a set of recesses in the first side of a die and a set of contours of a heat spreader form a set of intersecting channels across a first side of the die in multiple directions. FIG. 6 illustrates this embodiment with the addition of contours 624 to the die package 500. A die package 600, which also represents a fan-out wafer level packaging package, has similar components to the die package 500, namely: a die 606 having therein a set of recesses 626, an assembly substrate 602, one or more redistribution layers 628, solder balls 630, encapsulant 616, an intermediate layer 618, and a heat spreader 620 having intersecting contours indicated at 622 and 624. Also shown are front 640, back 642, left 644, and right 646 edges of the die 606. The die package 600 also includes two additional recesses that cut across the die 606 from its left edge 644 to its right edge 646. While these additional recesses are not visible given the perspective of a cross-sectional view 634, which is orientated similarly to the cross-sectional view 534, they align with the contours 624 of the heat spreader 620 shown in a top view 632.

The intersecting channels within the first side of the die 606 create a nonplanar surface on the die 606 that is more complex, in that is has more surface area, than the nonplanar surface created on the die 506 by the non-intersecting channels within the first side of the die 506 of the die package 500. The increased surface area can allow for more rapid cooling in certain situations. Having channels running in multiple directions also makes it easier to orientate the die package 600 with a fan or air flow so that moving air is directed along one or more of the channels. In another embodiment, a set of channels are formed across a die in multiple directions which do not intersect. Rather than being orthogonal, for example, two or more non-parallel channels having similar, but not identical, directions can be positioned within the first side of a die such that the channels do not intersect within the confines of the die.

In addition, channels need not be straight. A set of wavy channels or channels having any other pattern can be recessed into the first side of a die to facilitate the dissipation of heat from the die in accordance with the teachings herein. Further, channels of a given width at the first surface of a die can have different cross sections within the die. One channel might have a square base while another does not. A channel can even have a cross section that varies along its length.

The RCP packages 500 and 600 are both shown without thermal TSVs, but each die package can also include thermal TSVs in alternate embodiments. In particular embodiments, the die packages include a plurality of thermal TSVs disposed within the dies 506, 606 that are configured to transfer heat generated within the dies 506, 606 to the first side of the dies 506, 606, wherein the plurality of thermal TSVs are exposed at the first side of the dies 506, 606 in areas where the encapsulant is absent. For either die package 500 or 600, at least a portion of the plurality thermal TSVs can also have a higher spatial density within a portion of the die 506 or 606 that has an elevated operational temperature relative to an average operational temperature of the die 506 or 606.

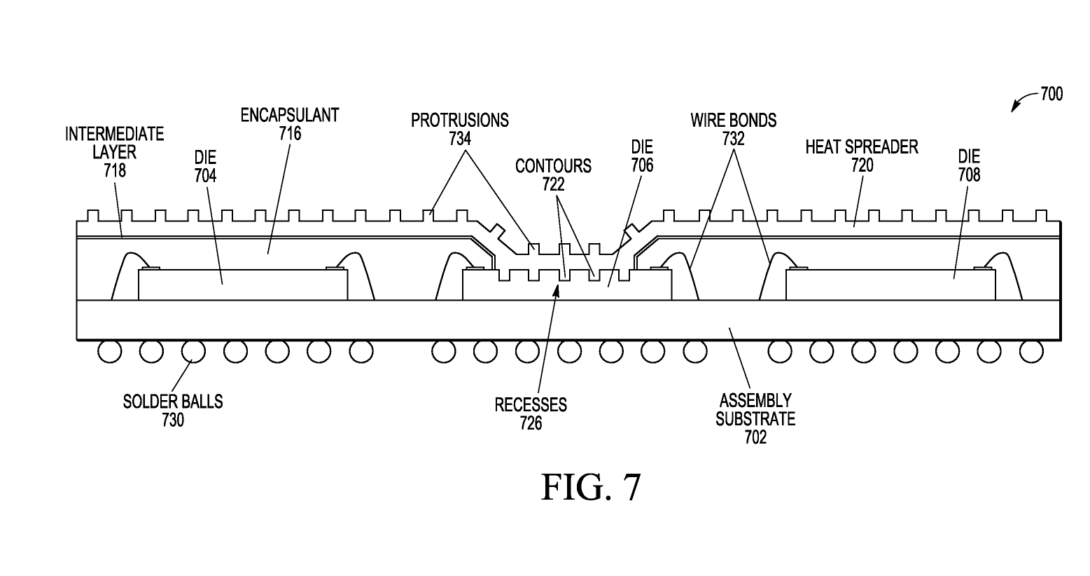

For a particular embodiment, a set of recesses is created in a topside of a die in an upright-chip configuration, and the first side of the die is the topside of the die. In this embodiment, the topside of the die is the active side of the die. Such an embodiment is illustrated in FIG. 7 by the die package 700. Within the die package 700 are three semiconductor dies 704, 706, 708 that are mounted to an assembly substrate 702 backside down. Wire bonds 732 connect the topsides of the dies 704, 706, 708 to a leadframe (not shown) within the assembly substrate 702 to establish signal connections between the dies 704, 706, 708 and solder balls 730. Encapsulant 716 is molded around the dies 704, 706, 708, and also around the wire bonds 732, to protect them from damage. After a set of recesses 726 are created in the die 706, an intermediate layer 718 and a metal-containing heat spreader 720 are deposited over the die 706 and the encapsulant 718. Contours 722 on a bottom side of the heat spreader 720 follow along and fill the recesses 726 formed in the die 706 in accordance with the present teachings. The intermediate layer 718 can also follow along and fill the recesses 726 formed in the die 706.

For the embodiment shown, the dies 704 and 708 of the three-die package 700 are not recessed nor do they make contact with the intermediate layer 718 or the heat spreader 720. The center die 706, however, is recessed and does make contact with the intermediate layer 718 and the heat spreader 720. This reflects a situation where only a portion or some of the dies within a die package generate enough heat to be singled out for heat dissipation as described herein. The center die 706 might represent a microprocessor, for example, with a billion or more transistors, while the adjacent dies 704, 708 might represent a read-only-memory (ROM) die and a controller die, which may not require additional cooling.

Because the first side of the die 706 is the active side of the die 706, the depth to which the recesses 726, and the portion of the heat spreader 720 that fills the recesses 726, penetrate into the first side of the die 706 is limited so as not to interfere with active electronic components underneath or adjacent to the recesses 726. In some embodiments, the recesses 726 penetrate only about one or two micrometers into the die 706, while in other embodiments, the recesses 726 can penetrate deeper into the die without exceeding the depth at which the active electronic components of the die 706 lie. The length and width shown for the contours 722 that fill the recesses 726 in the first side of the die 706 are exaggerated for conceptual clarity. For an actual implementation, the contours 722 and recesses 726 may have a much smaller area than that of the entire topside of the die 706.

One method of recessing the die 706 uses a chemical solution to etch the first side of the die 706. For an embodiment, a passivation coating protecting active components within the die 706 can also function as an etch-stop layer. Another method or recessing the die 706 uses a laser to score the topside of the die 706. The resulting plurality of indentations 726 can represent stippling, checkering, hatching, scalloping, dithering or any other pattern of recesses that increases the surface area of the topside of the die 706 without affecting the function of the active electronic components that lie underneath. Recessing dies can be done either before or after singulation of the dies from a semiconductor wafer. For a particular embodiment, the die 706 is recessed so that the recesses 726 are not co-located with active electronic components that reside on the first surface of the die 706. Because active electronic components are located near or at the first surface of the die 706, thermal TSVs are not included in the embodiment shown at 700 for the upright-chip configuration.

After depositing one or more thin films to form the intermediate layer 718, depositing a metal-containing layer over the recesses within the topside of the die 706 forms the heat spreader 720. The heat spreader 720 is formed to contact only the portion of the die 706 having the recesses 726, beyond which the heat spreader 720 transitions to a higher elevation to clear the sensitive wire bonds 732 and also the other dies 704, 708 which are covered by encapsulant 716. For the embodiment shown, a plurality of protrusions 734 are also positioned on the outwardly facing (directed away from the die 706 and the die package 700) surface of the heat spreader 720 to increase the surface area of the heat spreader 720 so that it may more effectively radiate heat drawn from the die 706 to the environment. Other embodiments described herein can also be implemented with a heat spreader having similar protrusions.

FIG. 8 provides additional detail about the intermediate layers 118, 518, 618, and 718 appearing in FIGS. 1, 5, 6, and 7, respectively. Specifically, FIG. 8 shows an oblique 802 and a cross-sectional 804 view of an intermediate layer 818 deposited between a semiconductor die 806 and a heat spreader 820, in accordance with an embodiment of the present teachings. For some embodiments, the intermediate layer 818 includes at least one of a barrier layer or a seed layer deposited between the first side of the die 806 and the metal-containing layer that forms the heat spreader 820. For the embodiment shown, a barrier layer 832 is deposited on the first side of the die 806, a seed layer 834 is deposited on the barrier layer 832, and the metal-containing layer that forms the heat spreader 820 is deposited on the seed layer 834.

In an embodiment, a material that adheres well to the first surface of the die 806 is used for the thin film that forms the barrier layer 832. Tungsten and alloys of primarily tungsten are well suited for use in the barrier layer 832 because they adhere well to organic compounds found within encapsulants and also to a passivation layer if one is used on the first surface of the die 806. Copper represents a less desirable choice for a barrier layer as copper might not adhere as well to organic compounds and might not sufficiently limit the diffusion of metal atoms into the die 806. In one embodiment, a titanium-tungsten alloy is used for the barrier layer 832 that is made up of approximately 10% titanium and 90% tungsten. The barrier layer 832 ranges in thickness of between about 100 angstroms (Å) and about 10,000 Å, and for a particular embodiment, has a thickness of about 1000 Å, or 0.1 μm.

In the cross-sectional view 804, thermal TSVs 810 exposed at the first surface of the die 806 make physical contact with the barrier layer 832. The barrier layer 832 is configured to facilitate the flow of heat from the thermal TSVs and also from the die 806 to the seed layer and into the heat spreader 820. For example, in addition to being thin, the material used for the seed layer might have a thermal conductivity in excess of 10 W/mK. For a particular embodiment, the metal-containing layer forming the heat spreader 820 is deposited over the first side of the die 806, without having an adhesive layer between the metal-containing layer 820 and the first side of the die 806. This also facilitates the flow of heat from the die 806 to the heat spreader 820, given that the thermal conductivity of thermal adhesives is typically poor in comparison to the thin films forming the intermediate layer 818.

The next thin film deposited onto the barrier layer 832 forms the seed layer 834. In an embodiment, the material used for the seed layer is selected to bond well with both the barrier layer 832 and the layer that is deposited onto the seed layer 834, which is shown as the metal-containing layer forming the heat spreader 820. The seed layer 834 can include, for instance, a metal such as copper, gold, aluminum, silver or alloys thereof. These metals have a higher thermal conductivity than tungsten or alloys that are primarily tungsten and bond well with both the barrier layer 832 and the metal used for the heat spreader 820.

In a particular embodiment, copper is used for both the seed layer 834 and the heat spreader 820, but is deposited differently for each layer. Methods used to deposit the seed layer 834 and/or the barrier layer 832 can include, but are not limited to: atomic layer deposition, chemical vapor deposition, physical vapor deposition, or cathode arc deposition. For a specific embodiment, both the seed layer 834 and the barrier layer 832 are deposited using a sputtering technique. The thickness of the seed layer 834 is generally between about 100 Å and about 10,000 Å, and for a particular embodiment has a thickness of approximately 2000 Å or 0.2 μm. In the embodiment shown, the metal-containing layer that forms the heat spreader 820 is deposited onto the seed layer 834.

In alternate embodiments, additional thin films are deposited between the barrier layer 832 and the heat spreader 820, each selected for a purpose and each adhering well to its neighboring layers. For example, where a third metal is used for the heat spreader 820, a first metal adheres best with the barrier layer 832 and is used for the seed layer 834. An additional layer of a second metal that bonds well to both the seed layer 834 and the heat spreader 820 is deposited between them when the third metal does not adhere well to the first metal.

The heat spreader 820 normally functions best when it has enough mass to operate as a heat sink for the die 806. For this reason, the heat spreader 820 has a greater thickness than the thin films included in the intermediate layer 818. For example, the heat spreader 820 may have a thickness of between about 100 μm and about 200 μm over the die 806, and for a particular embodiment, it has a thickness of approximately 100 μm. Alternatively, the heat spreader 820 may be thicker or thinner. In different embodiments, the metal of the heat spreader 820 is plated using an electrolytic or a chemical process. For a specific embodiment, copper is plated onto the seed layer 834 to form the heat spreader 820. In alternate embodiments, the heat spreader 820 could be deposited by evaporation, sputtering, or using another deposition technique.

Benefits of the present disclosure may include, but are not limited to the following: creating a set of recesses in a die to increase the surface area of the die, which allows a heat spreader with contours that conform to the recesses to more effectively draw heat out of the die; creating a distribution of thermal TSVs made from a thermally conductive material within a die, which allows the TSVs to conduct heat from an active side of the die to the recessed side of the die and into the heat spreader; and using one or more thin films in place of a thermal adhesive to affix the heat spreader to the recessed side of the die, wherein the thin films have a collective thermal conductivity that is greater than that of the thermal adhesive.

In the foregoing specification, specific embodiments have been described. However, one of ordinary skill in the art appreciates that various modifications and changes can be made without departing from the scope of the disclosure as set forth in the claims below. Accordingly, the specification and figures are to be regarded in an illustrative rather than a restrictive sense, and all such modifications are intended to be included within the scope of present teachings.

For the sake of brevity, conventional techniques related to semiconductor fabrication including those using conventional complementary metal-oxide semiconductor (CMOS) technology and other functional aspects of the systems (and the individual operating components of the systems) may not be described in detail. Moreover, the various IC embodiments described above (e.g., with respect to FIGS. 1-8) may be produced or fabricated using conventional semiconductor processing techniques, e.g., well-known CMOS techniques. Further a variety of well-known and common semiconductor materials may be used, e.g., traditional metals (aluminum, copper, gold, etc.), polysilicon, silicon dioxide, silicon nitride, silicon, gallium nitride, gallium arsenide, other semiconductor substrates, and the like. Furthermore, the connecting lines shown in the various figures contained herein are intended to represent example physical, thermal, and/or electrical couplings between the various elements. It should be noted that many alternative or additional physical, thermal, or electrical connections may be present in a practical embodiment.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

In this document, the terms “comprises,” “comprising,” “has,” “having,” “includes”, “including,” “contains,” “containing,” “made of,” or any other variation thereof, are intended to cover a non-exclusive inclusion, such that a process, method, article, or apparatus that comprises, has, includes, contains, is made of a list of elements does not include only those elements but may include other elements not expressly listed or inherent to such process, method, article, or apparatus. The terms “substantially,” “essentially,” “approximately,” “about,” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%.

As used herein, the terms “configured to,” “configured with,” “arranged to,” “arranged with,” “capable of,” and any like or similar terms mean that the referenced circuit elements have an internal physical arrangement (such as by virtue of a particular transistor or fabrication technology used) and/or physical coupling and/or connectivity with other circuit elements in an inactive state. This physical arrangement and/or physical coupling and/or connectivity (while in the inactive state) enable the circuit elements to perform stated functionality while in the active state of receiving and processing various signals or inputs to the circuit elements. A device or structure that is “configured” in a certain way is configured in at least that way, but may also be configured in ways that are not listed.

The above description refers to elements or features being “connected” or “coupled” together. As used here and, unless expressly stated otherwise, “coupled” means that one element or feature is directly or indirectly joined to (or is in direct or indirect communication with) another element feature, and not necessarily physically. As used herein, unless expressly stated otherwise, “connected” means that one element or feature is directly joined to (or is in direct communication with) another element or feature. Furthermore, although the various drawings shown herein depict certain example arrangement of elements, additional intervening elements, features, or components may be present in an actual embodiment (assuming that the functionality of the given circuit is not adversely affected).

In the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A method for enabling heat dissipation from a die assembly, the method comprising:
removing material from a first side of a die of the die assembly to create a set of recesses in the first side of the die; and
depositing a metal-containing layer over the first side of the die to form a heat spreader that contains a set of contours that fill the set of recesses in the first side of the die.

2. The method of claim 1 further comprising depositing an intermediate layer, comprising at least one of a barrier layer or a seed layer, between the first side of the die and the metal-containing layer.

3. The method of claim 2, wherein:
the barrier layer is deposited on the first side of the die;
the seed layer is deposited on the barrier layer; and
the metal-containing layer is deposited on the seed layer.

4. The method of claim 1, wherein the metal-containing layer is deposited over the first side of the die, without having an adhesive layer between the metal-containing layer and the first side of the die.

5. The method of claim 1, wherein a first recess of the set of recesses is created in the first side of the die and a first contour of the set contours of the heat spreader fills the first recess in a location over a portion of the die having an elevated operational temperature relative to an average operational temperature over the first side of the die.

6. The method of claim 1, wherein the set of recesses in the first side of the die and the set of contours of the heat spreader form a set of channels across the first side of the die in a single direction.

7. The method of claim 1, wherein the set of recesses in the first side of the die and the set of contours of the heat spreader form a set of intersecting channels across the first side of the die in multiple directions.

8. The method of claim 1, wherein the set of recesses in the first side of the die form a set of pits in the first side of the die.

9. The method of claim 1, wherein the set of recesses is created in a backside of the die in a flip-chip configuration, and the first side of the die is the backside of the die.

10. The method of claim 1, wherein the set of recesses is created in a topside of the die in an upright-chip configuration, and the first side of the die is the topside of the die.

11. The method of claim 1, wherein the die further includes a set of thermal vias, the method further comprising:
exposing, at the first side of the die, at least a portion of the set of thermal vias, wherein the metal-containing layer is deposited over the exposed portion of the thermal vias.

12. A die assembly, comprising:
an assembly substrate;
a die having a first side and a second opposing side, wherein the die is mounted to the assembly substrate at the second side and a set of recesses is formed in the first side of the die;
an encapsulant formed on the assembly substrate, wherein the encapsulant at least partially embeds the die within the die assembly, and the encapsulant is absent at least over the set of recesses formed in the first side of the die; and
a heat spreader affixed to the first side of the die and configured to conduct heat away from the die, wherein the heat spreader comprises a set of contours that fill the set of recesses formed in the first side of the die.

13. The die assembly of claim 12 further comprising a first thin film disposed between the first side of the die and the heat spreader, wherein the first thin film is configured to limit diffusion of metal into the die.

14. The die assembly of claim 13 further comprising a second thin film disposed between the first thin film and the heat spreader, wherein the second thin film is configured to affix the heat spreader to the first side of the die.

15. The die assembly of claim 12, wherein the die includes a plurality of thermal vias configured to transfer heat generated within the die to the first side of the die, wherein the plurality of thermal vias are exposed at the first side of the die where the encapsulant is absent.

16. The die assembly of claim 15, wherein at least a first portion of the plurality thermal vias have a higher spatial density within a portion of the die that has an elevated operational temperature relative to an average operational temperature of the die.

17. The die assembly of claim 12, wherein the set of recesses formed in the first side of the die comprise at least one of:
a set of pits formed in the first side of the die;
a set of channels formed across the first side of the die in a single direction; or
a set of channels formed across the first side of the die in multiple directions.

18. The die assembly of claim 12, wherein the die assembly comprises a fan-out wafer level packaging package.

19. A die assembly, comprising:
an assembly substrate;
a die having a first side and a second opposing side, wherein the die is mounted to the assembly substrate at the second side and a set of recesses is formed in the first side of the die, wherein the die further includes a plurality of thermal vias configured to transfer heat generated within the die to the first side of the die, wherein the plurality of thermal vias are exposed at the first side of the die;
an encapsulant formed on the assembly substrate, wherein the encapsulant at least partially embeds the die within the die assembly, and the encapsulant is absent at least over the set of recesses and over one or more areas where the plurality of thermal vias are exposed at the first side of the die;
a heat spreader affixed to the first side of the die and configured to conduct heat away from the die, wherein the heat spreader comprises a set of contours that fill the set of recesses formed in the first side of the die;
a first thin film disposed between the first side of the die and the heat spreader, wherein the first thin film is configured to limit diffusion of metal into the die; and
a second thin film disposed between the first thin film and the heat spreader, wherein the second thin film is configured to affix the heat spreader to the first side of the die.

20. The die assembly of claim 19, wherein at least a portion of the plurality thermal vias has a higher spatial density within a portion of the die that has an elevated operational temperature relative to an average operational temperature of the die.
